(19) United States
(12) Patent Application Publication
(10) Pub. No.: US 2024/0138195 A1
(43) Pub. Date: Apr. 25, 2024

(54) DISPLAY PANEL

(71) Applicant: Samsung Display Co., Ltd., Yongin-si (KR)

(72) Inventor: INYOUNG JUNG, Yongin-si (KR)

(21) Appl. No.: 18/235,722

(22) Filed: Aug. 17, 2023

(30) Foreign Application Priority Data
Oct. 18, 2022 (KR) 10-2022-0135113

(51) Int. Cl. H10K 59/122; H10K 59/131

(52) U.S. Cl. CPC H10K 59/122; H10K 59/131

(57) ABSTRACT

A display panel includes a base layer including a display area and a non-display area adjacent to the display area, a lower electrode on the base layer and overlapping the display area, a driving voltage line on the base layer and overlapping the non-display area, a pixel defining layer on the base layer, covering a portion of the lower electrode, and defining a light emitting opening, a light emitting pattern within the light emitting opening and on the lower electrode, a partition wall on the pixel defining layer and the driving voltage line and defining an upper opening corresponding to the light emitting opening, and an upper electrode on the light emitting pattern and in contact with an inner surface of the partition wall defining the upper opening, wherein the driving voltage line is in contact with the partition wall.

### CROSS-REFERENCE TO RELATED APPLICATION

This application claims priority to and the benefit of Korean Patent Application No. 10-2022-0135113, filed on Oct. 19, 2022, in the Korean Intellectual Property Office, the disclosure of which is incorporated by reference herein in its entirety.

### BACKGROUND

### 1. Field

Embodiments of the present disclosure are related to a display panel.

### 2. Description of the Related Art

Display devices such as televisions, monitors, smart phones, and tablet personal computers (PC) that provide images to users include panels that display images. Over the years, various display panels including liquid crystal display panels, organic light emitting display panels, electro wetting display panels, electrophoretic display panels, and the like have been developed.

The above information disclosed in this Background section is for enhancement of understanding of the background of the present disclosure, and therefore, it may contain information that does not constitute prior art.

### SUMMARY

Aspects of embodiments of the present disclosure are directed to a display panel including a configuration having an improved adhesion reliability.

According to some embodiments of the present disclosure, there is provided a display panel including: a base layer including a display area and a non-display area adjacent to the display area; a lower electrode on the base layer and overlapping the display area; a driving voltage line on the base layer and overlapping the non-display area; a pixel defining layer on the base layer, covering a portion of the lower electrode, and defining a light emitting opening; a light emitting pattern within the light emitting opening and on the lower electrode; a partition wall on the pixel defining layer and the driving voltage line and defining an upper opening corresponding to the light emitting opening; and an upper electrode on the light emitting pattern and in contact with an inner surface of the partition wall defining the upper opening, wherein the driving voltage line is in contact with the partition wall.

In some embodiments, the partition wall extends from a boundary between the display area and the non-display area in a direction away from the display area.

In some embodiments, the upper electrode and the driving voltage line are electrically connected.

In some embodiments, the partition wall includes: a first conductive layer having a first conductivity; and a second conductive layer having a second conductivity lower than the first conductivity, and on the first conductive layer.

In some embodiments, a thickness of the first conductive layer is greater than a thickness of the second conductive layer.

In some embodiments, an inner surface of the first conductive layer defines a first area of the upper opening, and an inner surface of the second conductive layer defines a second area of the upper opening, and the inner surface of the second conductive layer defining the second area is closer to a center of the lower electrode than the inner surface of the first conductive layer defining the first area in a cross sectional view.

In some embodiments, the display panel further includes: a lower encapsulation inorganic layer on the upper electrode and the partition wall; an encapsulation organic layer on the lower encapsulation inorganic layer; and an upper encapsulation inorganic layer on the encapsulation organic layer, wherein the lower encapsulation inorganic layer is in contact with a side surface of the first conductive layer and a lower surface of the second conductive layer.

In some embodiments, the display panel further includes: a capping pattern between the upper electrode and the lower encapsulation inorganic layer.

In some embodiments, the driving voltage line includes: a first voltage conductive layer including a first material; a second voltage conductive layer on the first voltage conductive layer and including a second material different from the first material; and a third voltage conductive layer on the second voltage conductive layer and including the first material.

In some embodiments, a conductivity of the first material is lower than that of the second material.

In some embodiments, a thickness of the second voltage conductive layer is greater than thicknesses of the first voltage conductive layer and the third voltage conductive layer.

In some embodiments, the first conductive layer and the second voltage conductive layer include the same material, and the second conductive layer, the first voltage conductive layer, and the third voltage conductive layer include the same material.

In some embodiments, the driving voltage line includes a first electrode layer and a second electrode layer on the first electrode layer, the second electrode layer being in contact with the partition wall.

According to some embodiments of the present disclosure, there is provided a display panel including: a base layer including a display area and a non-display area adjacent to the display area; a lower electrode on the base layer overlapping the display area; a driving voltage line on the base layer overlapping the non-display area; a pixel defining layer on the base layer, covering a portion of the lower electrode, and defining a light emitting opening; a light emitting pattern within the light emitting opening and on the lower electrode; a partition wall defining an upper opening corresponding to the light emitting opening; and an upper electrode on the light emitting pattern and in contact with an inner surface of the partition wall defining the upper opening, wherein the partition wall extends from a boundary between the display area and the non-display area in a direction away from the display area and electrically connects the upper electrode and the driving voltage line.

In some embodiments, the driving voltage line is in contact with the partition wall.

In some embodiments, the partition wall includes: a first conductive layer having a first conductivity; and a second conductive layer having a second conductivity lower than the first conductivity, and on the first conductive layer.

In some embodiments, an inner surface of the first conductive layer defines a first area of the upper opening, and an inner surface of the second conductive layer defines a second area of the upper opening, and the inner surface of the second conductive layer defining the second area is closer to a center of the lower electrode than the inner surface of the first conductive layer defining the first area in a cross section.

In some embodiments, the driving voltage line includes: a first voltage conductive layer including a first material; a second voltage conductive layer on the first voltage conductive layer and including a second material different from the first material; and a third voltage conductive layer on the second voltage conductive layer and including the first material, and wherein a conductivity of the first material is lower than a conductivity of the second material.

In some embodiments, the first conductive layer and the second voltage conductive layer include the same material, and wherein the second conductive layer, the first voltage conductive layer, and the third voltage conductive layer include the same material.

In some embodiments, the driving voltage line includes a first electrode layer and a second electrode layer on the first electrode layer, the second electrode layer being in contact with the partition wall.

### BRIEF DESCRIPTION OF THE DRAWINGS

The above and other objects and features of the present disclosure will become apparent by describing in detail embodiments thereof with reference to the accompanying drawings.

FIG. 1A is a perspective view of a display device according to some embodiments of the present disclosure.

FIG. 1B is an exploded perspective view of the display device according to some embodiments of the present disclosure.

FIG. 2 is a cross-sectional view of a display module of the display device according to some embodiments of the present disclosure.

FIG. 3 is a plan view of a display panel of the display device according to some embodiments of the present disclosure.

FIG. 4 is a circuit diagram of a pixel according to some embodiments of the present disclosure.

FIG. 5 is an enlarged plan view of a portion of a display area of the display panel according to some embodiments of the present disclosure.

FIG. 6 is a cross-sectional view of the display panel along the line I-I′ of FIG. 3.

FIG. 7 is a cross-sectional view of the display panel along the line II-II′ of FIG. 3.

FIG. 8 is an enlarged schematic view of an area corresponding to the area AA′ of FIG. 7.

FIG. 9 is an enlarged schematic view of an area corresponding to the area AA′ of FIG. 7.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

Unless otherwise defined, all terms (including technical terms and scientific terms) used in the present specification have the same meaning as commonly understood by those skilled in the art to which the present disclosure pertains. Furthermore, commonly used terms that are defined in a dictionary should be interpreted as having a meaning consistent with the meaning in the context of the related technology, and should not be interpreted in overly ideal or overly formal meanings unless explicitly defined herein.

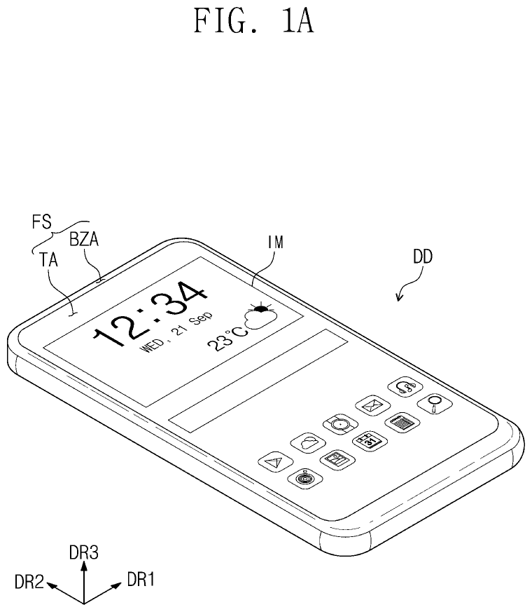

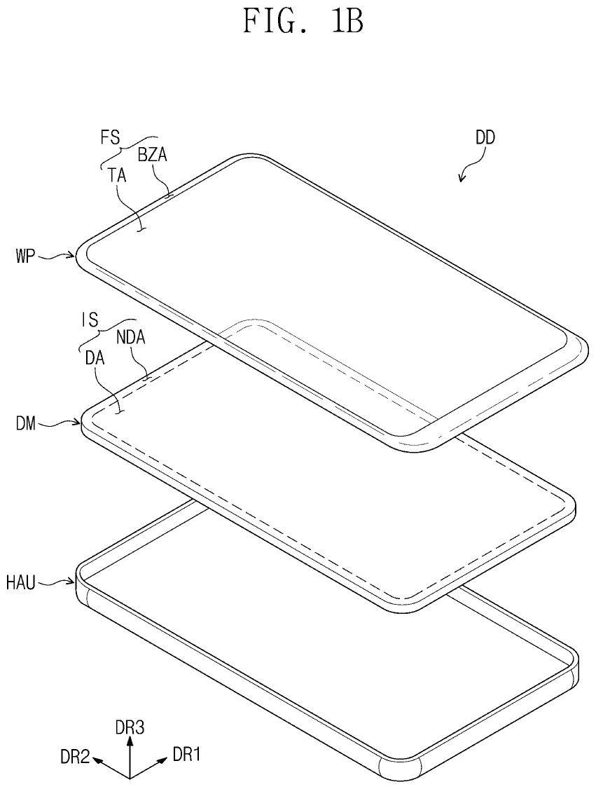

FIG. 1A is a perspective view of a display device DD according to some embodiments of the present disclosure, and FIG. 1B is an exploded perspective view of the display device DD according to some embodiments of the present disclosure.

In some embodiments, the display device DD may be a large electronic device such as a television, a monitor, or an external billboard. Further, the display device DD may be a small or medium-sized electronic device such as a personal computer (PC), a laptop, a personal digital terminal, a vehicle navigation unit, a game console, a smart phone, a tablet PC, or a camera. However, this is illustrative, and other display devices may be adopted as long as the display devices do not deviate from the concept of the present disclosure. FIGS. 1A and 1B illustrate examples in which the display device DD is a smart phone.

Referring to FIGS. 1A and 1B, the display device DD may display an image IM in a third direction DR3 on a display surface FS parallel to a first direction DR1 and a second direction DR2. The image IM may include a still image as well as a moving image. In FIG. 1, a watch window and icons are illustrated as one example of the image IM. The display surface FS on which the image IM is displayed may correspond to a front surface of the display device DD.

In the present embodiment, a front surface (e.g., an upper surface) and a rear surface (e.g., a lower surface) of each member are defined with respect to a direction in which the image IM is displayed (e.g., with respect to the projection direction of the image IM, DR3). The front surface and the rear surface may face each other in the third direction DR3, and a normal direction of each of the front and rear surfaces may be parallel to the third direction DR3. Directions indicated by the first to third directions DR1, DR2, and DR3 are relative concepts and may be changed to other directions. In the present specification, phrase “when viewed on a plane” and “in a plan view” may refer to a state of “when viewed in the third direction DR3”.

Referring to FIG. 1B, the display device DD may include a window WP, a display module DM, and a housing HAU. The window WP and the housing HAU may be coupled to each other to constitute an exterior of the display device DD.

The window WP may include an optically transparent insulating material. For example, the window WP may include glass, plastic, and/or the like. A front surface of the window WP may define the display surface FS of the display device DD. The display surface FS may include a transparent area TA and a bezel area BZA. The transparent area TA may be an optically transparent area. For example, the transparent area TA may be an area having a visible light transmittance of about 90% or more.

The bezel area BZA may be an area having a relatively lower light transmittance than that of the transparent area TA. The bezel area BZA may define a shape of the transparent area TA. The bezel area BZA may be adjacent to the transparent area TA and surround the transparent area TA. However, this is illustrative, and the bezel area BZA of the window WP may be omitted. The window WP may include at least one functional layer of a fingerprint prevention layer, a hard coating layer, and a reflection prevention layer, and is not limited to some embodiments.

The display module DM may be disposed below the window WP. The display module DM may be a component that substantially generates the image IM (see, e.g., FIG. 1A). The image IM generated by the display module DM is disposed on a display surface IS of the display module DM and is visually recognized by a user from the outside through the transparent area TA.

The display module DM may include a display area DA and a non-display area NDA. The display area DA may be an area that is activated according to an electric signal. The non-display area NDA may be adjacent to the display area DA. The non-display area NDA may surround the display area DA. The non-display area NDA is an area covered by the bezel area BZA and may not be visually recognized from the outside by a user.

The housing HAU may be coupled to the window WP. The housing HAU may be coupled to the window WP to provide an inner space (e.g., a set or predetermined inner space). The display module DM may be accommodated in the inner space.

The housing HAU may include a material having a relatively high rigidity. For example, the housing HAU may include a plurality of frames and/or plates made of glass, plastic, metal, or combinations thereof. The housing HAU may stably protect components of the display device DD accommodated in the inner space from an external impact.

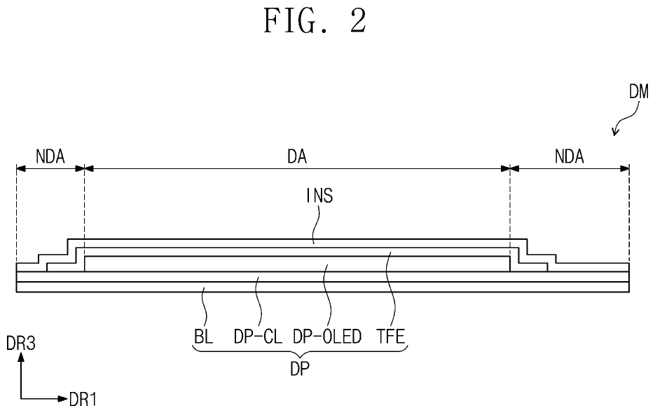

FIG. 2 is a cross-sectional view of the display module DM according to some embodiments of the present disclosure.

Referring to FIG. 2, the display module DM may include a display panel DP and an input sensor INS. The display device DD (see, e.g., FIG. 1A) according to some embodiments of the present disclosure may further include a protective member disposed on a lower surface of the display panel DP or a reflection prevention member and/or a window member disposed on an upper surface of the input sensor INS.

The display panel DP may be a light emitting display panel. However, this is illustrative, and the present disclosure is not particularly limited thereto. For example, the display panel DP may be an organic light emitting display panel or an inorganic light emitting display panel. A light emitting layer in the organic light emitting display panel may include an organic light emitting material. A light emitting layer in the inorganic light emitting display panel may include a quantum dot, a quantum rod, a micro light emitting diode (LED) and/or the like. Hereinafter, the display panel DP will be described as the organic light emitting display panel.

The display panel DP may include a base layer BL, a circuit element layer DP-CL, a display element layer DP-OLED, and a thin film encapsulation layer TFE, which are arranged on the base layer BL. The input sensor INS may be directly disposed on the thin film encapsulation layer TFE. In the present specification, the language “component A is directly disposed on component B” means that no adhesive layer is disposed between component A and component B.

The base layer BL may include at least one plastic film. The base layer BL is a flexible substrate and may include a plastic substrate, a glass substrate, a metal substrate, or an organic/inorganic composite material substrate. The display area DA and the non-display area NDA described in FIG. 1B may be equally defined on the base layer BL.

The circuit element layer DP-CL may include at least one insulating layer and a circuit element. The insulating layer includes at least one inorganic layer and at least one organic layer. The circuit element includes signal lines, a driving circuit of a pixel, and the like.

The display element layer DP-OLED may include a partition wall and a light emitting element. The light emitting element may include a lower electrode, a light emitting pattern, and an upper electrode.

The thin film encapsulation layer TFE may include a plurality of thin films. Some thin films may be arranged to improve optical efficiency, and some thin films may be arranged to protect organic light emitting diodes.

The input sensor INS acquires coordinate information of an external input. The input sensor INS may have a multilayer structure. The input sensor INS may include a single layered or multi-layered conductive layer. Further, the input sensor INS may include a single layered or multi-layered insulating layer. The input sensor INS may detect an external input in a capacitive manner. However, this is illustrative, and the present disclosure is not limited thereto. For example, in some embodiments, the input sensor INS may also detect an external input in an electromagnetic induction manner or a pressure sensing manner. In some embodiments of the present disclosure, the input sensor INS may be omitted.

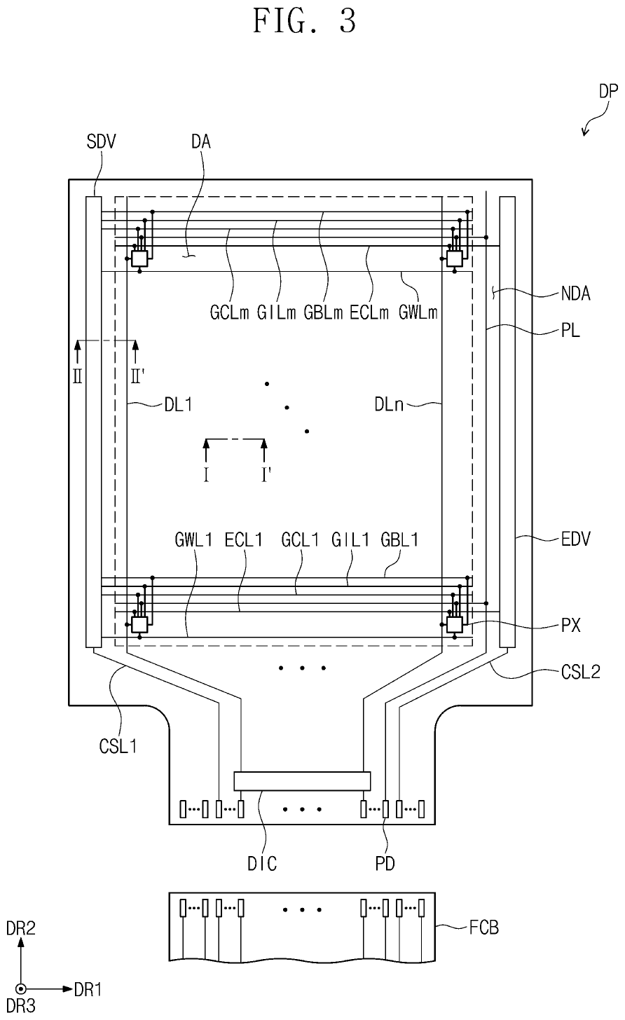

FIG. 3 is a plan view of the display panel DP according to some embodiments of the present disclosure.

Referring to FIG. 3, the display area DA and the non-display area NDA around the display area DA may be defined in the display panel DP. The display area DA and the non-display area NDA may be distinguished depending on whether a pixel PX is disposed. The pixel PX may be disposed in the display area DA. A scan driving unit SDV, a data driving unit, and a light emitting driving unit EDV may be arranged in the non-display area NDA. The data driving unit may be a portion of a circuit included in a driving chip DIC.

The display panel DP may include the pixels PX, initialization scan lines GIL1 to GILm, compensation scan lines GCL1 to GCLm, write scan lines GWL1 to GWLm, black scan lines GBL1 to GBLm, light emitting control lines ECL1 to ECLm, data lines DL1 to DLn, first and second control lines CSL1 and CSL2, a driving voltage line PL, and a plurality of pads PD. In this case, “m” and “n” are natural numbers greater than or equal to two.

The pixels PX may be connected to the initialization scan lines GIL1 to GILM, the compensation scan lines GCL1 to GCLm, the write scan lines GWL1 to GWLm, the black scan lines GBL1 to GBLm, the light emitting control lines ECL1 to ECLm, and the data lines DL1 to DLn.

The initialization scan lines GIL1 to GILM, the compensation scan lines GCL1 to GCLm, the write scan lines GWL1 to GWLm, and the black scan lines GBL1 to GBLm may extend in the first direction DR1 and may be electrically connected to the scan driving unit SDV. The data lines DL1 to DLn may extend in the second direction DR2 and may be electrically connected to the driving chip DIC. The light emitting control lines ECL1 to ECLm may extend in the first direction DR1 and may be electrically connected to the light emitting driving unit EDV.

The driving voltage line PL may include a portion extending in the first direction DR1 and a portion extending in the second direction DR2. The portion extending in the first direction DR1 and the portion extending in the second direction DR2 may be arranged in different layers. The driving voltage line PL may provide a driving voltage to the pixels PX.

The first control line CSL1 may be connected to the scan driving unit SDV. The second control line CSL2 may be connected to the light emitting driving unit EDV.

The driving chip DIC, the driving voltage line PL, the first control line CSL1, and the second control line CSL2 may be electrically connected to the pads PD. A flexible circuit film FCB may be electrically connected to the pads PD through an anisotropic conductive adhesive layer.

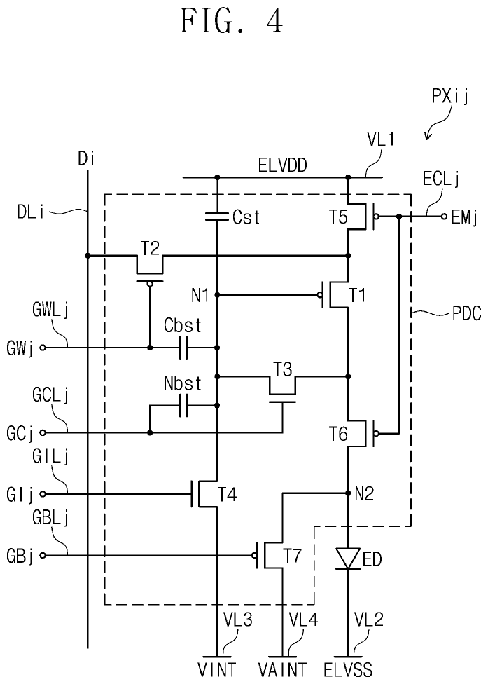

FIG. 4 is an circuit diagram of a pixel PXij according to some embodiments of the present disclosure.

FIG. 4 exemplarily illustrates an circuit diagram of one pixel PXij among the plurality of pixels PX (see, e.g., FIG. 3). Because the plurality of pixels PX have the same circuit structure, a detailed description of the other pixels PX will be omitted because a description of a circuit structure of the pixel PXij is present.

Referring to FIGS. 3 and 4, the pixel PXij is connected to an i^{th} data line DLi among the data lines DL1 to DLn, a j^{th} initialization scan line GILj among the initialization scan lines GIL1 to GILm, a j^{th} compensation scan line GCLj among the compensation scan lines GCL1 to GCLm, a j^{th} write scan line GWLj among the write scan lines GWL1 to GWLm, a j^{th} black scan line GBLj among the black scan lines GBL1 to GBLm, a j^{th} light emitting control line ECLj among the light emitting control lines ECL1 to ECLm, first and second driving voltage lines VL1 and VL2, and first and second initialization voltage lines VL3 and VL4. Here, i is an integer greater than or equal to 1 and less than or equal to n, and j is an integer greater than or equal to 1 and less than or equal to m.

The pixel PXij includes a light emitting element ED and a pixel circuit PDC. The light emitting element ED may be a light emitting diode. As an example of the present disclosure, the light emitting element ED may be an organic light emitting diode including an organic light emitting layer, but the present disclosure is not particularly limited thereto. The pixel circuit PDC may control the amount of a current flowing in the light emitting element ED in response to a data signal Di. The light emitting element ED may emit light having a luminance (e.g., a set or predetermined luminance) that corresponds to the amount of current provided from the pixel circuit PDC.

The pixel circuit PDC may include first to seventh transistors T1, T2, T3, T4, T5, T6, and T7, and first to third capacitors Cst, Cbst, and Nbest. According to the present disclosure, a configuration of the pixel circuit PDC is not limited to the embodiments illustrated in FIG. 4. The pixel circuit PDC illustrated in FIG. 4 is merely an example, and a configuration of the pixel circuit PDC may be modified and implemented in a suitable manner.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T6 may be LTPS transistors.

In some embodiments, the first transistor T1, which directly affects the brightness of the light emitting element ED, includes a highly reliable polycrystalline silicon semiconductor layer, and therefore, a high-resolution display device may be implemented. Because the oxide semiconductor has high carrier mobility and low leakage current, a voltage drop is not large even when a driving time is long. That is, because a change in a color of the image due to the voltage drop is not large even during low-frequency driving, low frequency driving may be performed. In this way, because the oxide semiconductor has a low leakage current, at least one among the third transistor T3 and the fourth transistor T4 connected to a gate electrode of the first transistor T1 may be adopted as the oxide transistor, and thus leakage current that may flow to the gate electrode may be prevented or substantially reduced, and at the same time, power consumption may be reduced.

Some of the first to seventh transistors T1, T2, T3, T4, T5, T6, and T7 may be P-type transistors and the others thereof may be N-type transistors. For example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to the present disclosure is not limited to some embodiments illustrated in FIG. 4. The pixel circuit PDC illustrated in FIG. 4 is merely an example and a configuration of the pixel circuit PDC may be modified and implemented in a suitable manner. For example, all the first to seventh transistors T1, T2, T3, T4, T5, T6, and T7 may be P-type transistors or N-type transistors. In some examples, the first, second, fifth, and sixth transistors T1, T2, T5, and T6 may be P-type transistors, and the third, fourth, and seventh transistors T3, T4 and T7 may be N-type transistors.

The j^{th} initialization scan line GILj, the j^{th} compensation scan line GCLj, the j^{th} write scan line GWLj, the j^{th} black scan line GBLj, and the j^{th} light emitting control line ECLj may transmit, to the pixel PXij, a j^{th} initialization scan signal GIj, a j^{th} compensation scan signal GCj, a j^{th} write scan signal GW, a j^{th} black scan signal GBj, and a j^{th} light emitting control signal EMj, respectively. The i^{th} data line DLi transmits an i^{th} data signal Di to the pixel PXij. The i^{th} data signal Di may have a voltage level corresponding to an image signal input to the display device DD (see, e.g., FIG. 1).

The first and second driving voltage lines VL1 and VL2 may transmit, to the pixel PXij, a first driving voltage ELVDD and a second driving voltage ELVSS, respectively. Further, the first and second initialization voltage lines VL3 and VL4 may transmit, to the pixel PXij, a first initialization voltage VINT and a second initialization voltage VAINT, respectively.

The first transistor T1 is connected between the first driving voltage line VL1 that receives the first driving voltage ELVDD and the light emitting element ED. The first transistor T1 includes a first electrode connected to the first driving voltage line VL1 via the fifth transistor T5, a second electrode connected to a pixel electrode (e.g., an anode) of the light emitting element ED via the sixth transistor T6, and a third electrode (for example, a gate electrode) connected to one end (for example, at first node N1) of the first capacitor Cst. The first transistor T1 may receive the i^{th} data signal Di transmitted by the i^{th} data line DLi according to a switching operation of the second transistor T2 and supply a driving current to the light emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (for example, a gate electrode) connected to the j^{th} write scan line GWLj. The second transistor T2 may be turned on according to the write scan signal GW transmitted through the j^{th} write scan line GWLj and may transmit the i^{th} data signal Di transmitted from the i^{th} data line DLi to the first electrode of the first transistor T1. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j^{th} compensation scan line GCLj. The third transistor T3 may be turned on according to the j^{th} compensation scan signal GCj transmitted through the j^{th} compensation scan line GCLj, may connect the third electrode of the first transistor T1 and the second electrode of the first transistor T1 to each other, and thus may diode-connect the first transistor T1. One end of the third capacitor Nbst may be connected to the third electrode of the third transistor T3, and the other end of the third capacitor Nbst may be connected to the first node N1.

The fourth transistor T4 is connected between the first initialization voltage line VL3 to which the first initialization voltage VINT is applied and the first node N1. The fourth transistor T4 includes a first electrode connected to the first initialization voltage line VL3 to which the first initialization voltage VINT is applied, a second electrode connected to the first node N1, and a third electrode (for example, a gate electrode) connected to the j^{th} initialization scan line GILj. The fourth transistor T4 is turned on according to the j^{th} initialization scan signal GIj transmitted through the j^{th} initialization scan line GILj. The turned-on fourth transistor T4 transmits the first initialization voltage VINT to the first node N1 and initializes a potential (e.g., voltage) of the third electrode of the first transistor T1 (that is, a potential or voltage of the first node N1).

The fifth transistor T5 includes a first electrode connected to the first driving voltage line VL1, a second electrode connected to the first electrode of the first transistor T1, and a third electrode (for example, a gate electrode) connected to the j^{th} light emitting control line ECLj. The sixth transistor T6 includes a first electrode connected to the second electrode of the first transistor T1, a second electrode connected to the pixel electrode of the light emitting element ED, and a third electrode (for example, a gate electrode) connected to the j^{th} light emitting control line ECLj.

The fifth and sixth transistors T5 and T6 are simultaneously (e.g., concurrently) turned on according to the j^{th} light emitting control signal EMj transmitted through the j^{th} light emitting control line ECLj. The first driving voltage ELVDD applied through the turned-on fifth transistor T5 may be compensated for through the diode-connected first transistor T1 and may then be transmitted to the light emitting element ED through the sixth transistor T6.

The seventh transistor T7 includes a first electrode connected to the second initialization voltage line VL4 to which the second initialization voltage VAINT is applied, a second electrode connected to the second electrode of the sixth transistor T6, and a third electrode (for example, a gate electrode) connected to the j^{th} black scan line GBLj. The second initialization voltage VAINT may have a voltage level lower than or equal to the first initialization voltage VINT.

One end of the first capacitor Cst is connected to the third electrode of the first transistor T1, and the other end of the first capacitor Cst is connected to the first driving voltage line VL1. A cathode of the light emitting element ED may be connected to the second driving voltage line VL2 that transmits the second driving voltage ELVSS. The second driving voltage ELVSS may have a voltage level lower than the first driving voltage ELVDD.

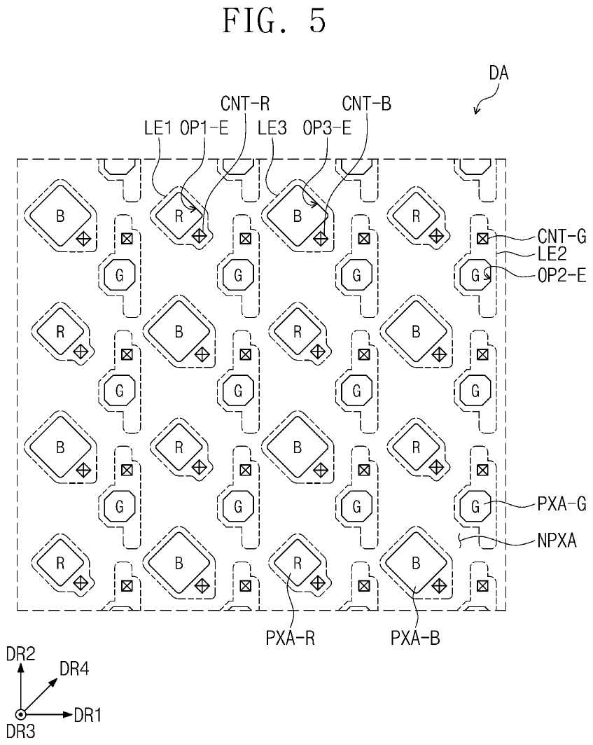

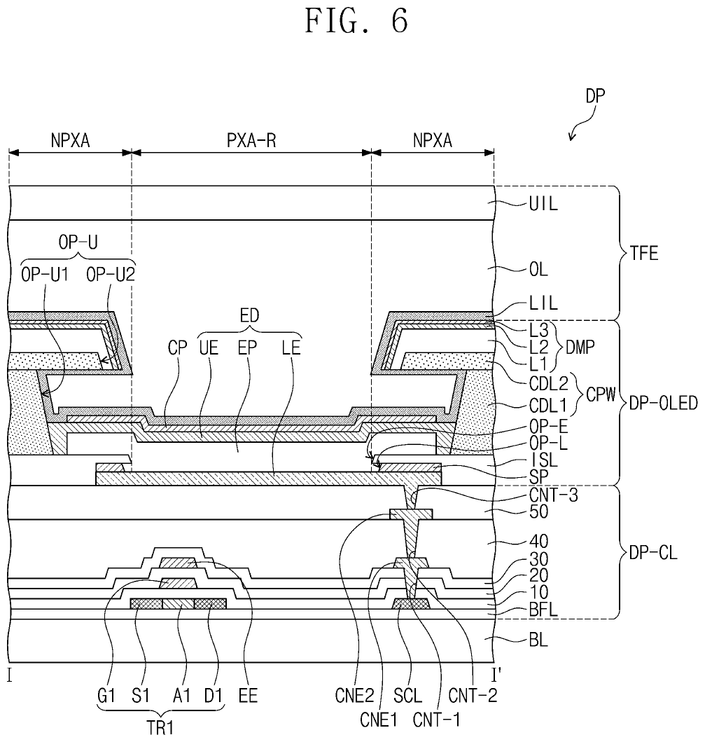

FIG. 5 is an enlarged plan view of a portion of the display area DA of the display panel DP according to some embodiments of the present disclosure. FIG. 6 is a cross-sectional view of the display panel DP along the line I-I′ of FIG. 3. FIG. 5 illustrates a flat surface of the display module DM (see, e.g., FIG. 2) when viewed from the display surface IS (see, e.g., FIG. 2) and illustrates arrangement of light emitting areas PXA-R, PXA-G, and PXA-B.

Referring to FIGS. 5 and 6, the display area DA may include the first to third light emitting areas PXA-R, PXA-G, and PXA-B and a non-light emitting area NPXA surrounding the first to third light emitting areas PXA-R, PXA-G, and PXA-B. The display panel DP may include a first light emitting element, a second light emitting element, and a third light emitting element. In FIG. 6, a structure of the light emitting element ED is representatively illustrated, and structures of the first to third light emitting elements may be substantially the same as the structure of the light emitting element ED.

The first light emitting element may include a first lower electrode LE1, a first light emitting pattern, and a first upper electrode. The second light emitting element may include a second lower electrode LE2, a second light emitting pattern, and a second upper electrode. The third light emitting element may include a third lower electrode LE3, a third light emitting pattern, and a third upper electrode. In some embodiments, the first light emitting pattern may provide red light, the second light emitting pattern may provide green light, and the third light emitting pattern may provide blue light.

Referring to FIG. 5, the first to third light emitting areas PXA-R, PXA-G, and PXA-B may respectively correspond to areas from which light provided from the first to third light emitting elements is emitted. In FIG. 5, for convenience of description, only the first to third lower electrodes LE1, LE2, and LE3 among the components of the first to third light emitting elements are illustrated as an example. The first to third light emitting areas PXA-R, PXA-G, and PXA-B may be classified according to the color of the light emitted toward the outside of the display module DM (see, e.g., FIG. 2).

The first to third light emitting areas PXA-R, PXA-G, and PXA-B may provide first to third color lights having different colors, respectively. For example, the first color light may be red light, the second color light may be green light, and the third color light may be blue color. However, examples of the first to third color lights are not necessarily limited to the above example.

The first light emitting area PXA-R may be defined as an area exposed by a light emitting opening OP1-E on an upper surface of the first lower electrode LE1. The second light emitting area PXA-G may be defined as an area exposed by a light emitting opening OP2-E on an upper surface of the second lower electrode LE2. The third light emitting area PXA-B may be defined as an area exposed by a light emitting opening OP3-E on an upper surface of the third lower electrode LE3. The light emitting openings OP1-E, OP2-E, and OP3-E may be defined in a pixel defining layer ISL (see, e.g., FIG. 6) covering portions of the lower electrodes LE1, LE2, and LE3, the detailed description of which will be made below.

The non-light emitting area NPXA may set boundaries between the first to third light emitting areas PXA-R, PXA-G, and PXA-B and prevent or substantially reduce color mixing between the first to third light emitting areas PXA-R, PXA-G, and PXA-B.

As shown in FIG. 5, a plurality of each of the first to third light emitting areas PXA-R, PXA-G, and PXA-B may be provided and may be repeatedly arranged in a set or predetermined pattern within the display area DA. For example, the first and third light emitting areas PXA-R and PXA-B may be alternately arranged in the first direction DR1 to constitute a “first group.” The second light emitting areas PXA-G may be arranged in the first direction DR1 to constitute a “second group.” A plurality of each of the “first group” and the “second group” may be provided, and the “first groups” and the “second groups” may be alternately arranged in the second direction DR2.

One second light emitting area PXA-G may be spaced apart from one first light emitting area PXA-R or one third light emitting area PXA-B in a fourth direction DR4. The fourth direction DR4 may be defined as a direction crossing (e.g., diagonal to) the first direction DR1 and the second direction DR2.

While FIG. 5 illustrates an example of a particular arrangement of the first to third light emitting areas PXA-R, PXA-G, and PXA-B, the present disclosure is not limited thereto, and the first to third light emitting areas PXA-R, PXA-G, and PXA-B may be arranged in various suitable forms. For example, the first to third light emitting areas PXA-R, PXA-G, and PXA-B may have a pentile arrangement as illustrated in FIG. 5 or have a stripe arrangement, a diamond arrangement, or the like.

The first to third light emitting areas PXA-R, PXA-G, and PXA-B may have various shapes on a plane (e.g., from a plan view). For example, the first to third light emitting areas PXA-R, PXA-G, and PXA-B may each have, for example, a polygonal shape, a circular shape, or an elliptic shape. FIG. 5 illustrates an example of the first and third light emitting areas PXA-R and PXA-B having a quadrangular shape (or a diamond shape) and the second light emitting area PXA-G having an octagonal shape in a plane.

The first to third light emitting areas PXA-R, PXA-G, and PXA-B may have the same shape on a plane (e.g., the same shape from a plan view) or may have at least partially different shapes. FIG. 5 illustrates an example of the first and third light emitting areas PXA-R and PXA-B having the same shape and the second light emitting area PXA-G having a shape different from that of the first and third light emitting areas PXA-R and PXA-B on a plane.

At least some of the first to third light emitting areas PXA-R, PXA-G, and PXA-B may have different areas on a plane. In some embodiments, an area of the first light emitting area PXA-R emitting red light may be greater than an area of the second light emitting area PXA-G emitting green light and may be smaller than an area of the third light emitting area PXA-B emitting blue light. However, a size relationship between the areas of the first to third light emitting areas PXA-R, PXA-G, and PXA-B according to the emitted color is not limited thereto and may be suitably varied depending on a design of the display module DM (see, e.g., FIG. 2). Further, the present disclosure is not limited thereto, and the first to third light emitting areas PXA-R, PXA-G, and PXA-B may also have the same area on a plane (e.g., the same area from a plan view).

The shape, the area, the arrangement, and the like of the first to third light emitting areas PXA-R, PXA-G, and PXA-B of the display module DM (see, e.g., FIG. 2) of the present disclosure may be variously designed in a suitable manner according to the color of the emitted light or the size and configuration of the display module DM (see, e.g., FIG. 2) and are not limited to some embodiments illustrated in FIG. 5.

Connection contact holes CNT-R, CNT-G, and CNT-B may include the first connection contact hole CNT-R, the second connection contact hole CNT-G, and the third connection contact hole CNT-B. The first to third lower electrodes LE1, LE2, and LE3 may be connected to the pixel circuits PDC (see, e.g., FIG. 4) inside the circuit element layer DP-CL (see, e.g., FIG. 2) through the first to third connection contact holes CNT-R, CNT-G, and CNT-B. For example, the first lower electrode LE1 may be connected to a pixel circuit corresponding to the first lower electrode LE1 through the first connection contact hole CNT-R, the second lower electrode LE2 may be connected to a pixel circuit corresponding to the second lower electrode LE2 through the second connection contact hole CNT-G, and the third lower electrode LE3 may be connected to a pixel circuit corresponding to the third lower electrode LE3 through the third connection contact hole CNT-B.

The first to third connection contact holes CNT-R, CNT-G, and CNT-B may be spaced apart from the first to third light emitting areas PXA-R, PXA-G, and PXA-B defined in the first to third lower electrodes LE1, LE2, and LE3, respectively. However, this is illustrative, and the first to third connection contact holes CNT-R, CNT-G, and CNT-B may overlap the first to third light emitting areas PXA-R, PXA-G, and PXA-B defined in the first to third lower electrodes LE1, LE2, and LE3, respectively.

Referring to FIG. 6, the display panel DP may include the base layer BL, the circuit element layer DP-CL, the display element layer DP-OLED, and the thin film encapsulation Layer TFE. A description of the base layer BL, the circuit element layer DP-CL, the display element layer DP-OLED, and the thin film encapsulation layer TFE of FIG. 6 may be the same or substantially the same as that provided with reference to FIG. 2. Therefore, in the interest of brevity, the description of elements having the same reference numerals may not be repeated here.

The display panel DP may include a plurality of insulating layers, a plurality of semiconductor patterns, a plurality of conductive patterns, a plurality of signal lines, and the like. The insulating layer, the semiconductor layer, and the conductive layer are formed by coating, deposition, or the like. Thereafter, the insulating layer, the semiconductor layer, and the conductive layer may be selectively patterned by photolithography and etching. In this manner, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include a buffer layer BFL, a transistor TR1, a signal transmission area SCL, first to fifth insulating layers 10, 20, 30, 40, and 50, an electrode EE, and a plurality of connection electrodes CNE1 and CNE2.

The buffer layer BFL may be disposed on the base layer BL. The buffer layer BFL may improve a coupling force between the base layer BL and the semiconductor pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon. However, the present disclosure is not limited thereto, and the semiconductor pattern may include amorphous silicon, a metal oxide, or the like. FIG. 6 merely illustrates a portion of the semiconductor pattern, and the semiconductor patterns may be further arranged in the plurality of light emitting areas PXA-R, PXA-G, and PXA-B. The semiconductor pattern may be arranged in a specific manner across the plurality of light emitting areas PXA-R, PXA-G, and PXA-B. The semiconductor pattern may have a different electrical property depending on whether or not the semiconductor pattern is doped. The semiconductor pattern may include a first area having a high doping concentration and a second area having a low doping concentration. The first area may be doped with an N-type dopant or a P-type dopant. A P-type transistor may include the first area doped with the P-type dopant.

A conductivity of the first area may be greater than a conductivity of the second area, and the first area may substantially serve as an electrode or a signal line. The second area may substantially correspond to an active area (or a channel) of a transistor. In other words, a portion of the semiconductor pattern may be the active area of the transistor, another portion of the semiconductor pattern may be a source or a drain of the transistor, and yet another portion of the semiconductor pattern may be a conductive area.

As illustrated in FIG. 6, a source S1, an active A1, and a drain D1 of the transistor TR1 may be formed from the semiconductor pattern. Further, FIG. 6 illustrates a portion of the signal transmission area SCL formed from the semiconductor pattern. The signal transmission area SCL may be connected to the drain D1 of the transistor TR1 in a plan view.

The first to fifth insulating layers 10, 20, 30, 40, and 50 may be arranged on the buffer layer BFL. The first to fifth insulating layers 10, 20, 30, 40, and 50 may be inorganic layers or organic layers.

The first insulating layer 10 may be disposed on the buffer layer BFL. A gate G1 may be disposed on the first insulating layer 10. The second insulating layer 20 may be disposed on the first insulating layer 10 to cover the gate G1. The electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transmission area SCL through a contact hole CNT-1 passing through the first to third insulating layers 10 to 30. The fourth insulating layer 40 may be disposed on the third insulating layer 30 to cover the first connection electrode CNE1. In some examples, the fourth insulating layer 40 may be an organic layer.

The second connection electrode CNE2 may be disposed on the fourth insulating layer 40. The second connection electrode CNE2 may be connected to the first connection electrode CNE1 through a contact hole CNT-2 passing through the third and fourth insulating layers 30 and 40. The fifth insulating layer 50 may be disposed on the fourth insulating layer 40 to cover the second connection electrode CNE2. In some examples, the fifth insulating layer 50 may be an organic layer.

The display element layer DP-OLED may be disposed on the circuit element layer DP-CL. The display element layer DP-OLED may include the light emitting element ED, a sacrificial pattern SP, the pixel defining layer ISL, a partition wall CPW, and a dummy pattern DMP.

The light emitting element ED may include a lower electrode LE, a light emitting pattern EP, and an upper electrode UE. The first to third light emitting elements may each include substantially the same configuration of the light emitting element ED of FIG. 6. That is, the description related to the lower electrode LE, the light emitting pattern EP, and the upper electrode UE may be equally applied to all of the lower electrodes, the light emitting patterns, and the upper electrodes of the first to third light emitting elements.

The lower electrode LE may be disposed on the fifth insulating layer 50 of the circuit element layer DP-CL. The lower electrode LE may be a transmissive electrode, a translucent electrode, or a reflective electrode. The lower electrode LE may be connected to the second connection electrode CNE2 through a connection contact hole CNT-3 defined through the fifth insulating layer 50. Thus, the lower electrode LE may be electrically connected to the signal transmission area SCL through the first and second connection electrodes CNE1 and CNE2 and thus electrically connected to the corresponding circuit element.

The sacrificial pattern SP may be disposed on an upper surface of the lower electrode LE. A lower opening OP-L through which a portion of the upper surface of the lower electrode LE is exposed may be defined in the sacrificial pattern SP. In some examples, the sacrificial pattern SP may include an amorphous transparent conductive oxide. According to the present disclosure, in a process of etching the sacrificial pattern SP to form the lower opening OP-L, the lower electrode LE may be prevented from being damaged due to the etching or damage thereto may be substantially reduced.

The pixel defining layer ISL may be disposed on the fifth insulating layer 50 of the circuit element layer DP-CL. The pixel defining layer ISL may cover a portion of the lower electrode LE and the sacrificial pattern SP. A light emitting opening OP-E may be defined in the pixel defining layer ISL. The light emitting opening OP-E may correspond to the lower opening OP-L of the sacrificial pattern SP.

In a plan view, the light emitting opening OP-E may overlap the lower opening OP-L, and an area of the light emitting opening OP-E may be smaller than an area of the lower opening OP-L. For example, the entirety of the light emitting opening OP-E may be overlapped by the lower opening OP-L, and the two openings may have a common center, in a plan view. That is, in a plan view, an inner surface of the pixel defining layer ISL defining the light emitting opening OP-E may be closer to a center of the lower electrode LE than an inner surface of the sacrificial pattern SP defining the lower opening OP-L. A portion of the pixel defining layer ISL closer to the center of the lower electrode LE, in a plan view, than the inner surface of the sacrificial pattern SP defining the lower opening OP-L may be defined as a tip portion of the pixel defining layer ISL.

In some examples, the pixel defining layer ISL may include an inorganic insulating material. For example, the pixel defining layer ISL may include a silicon nitride (SiNx) and/or the like. The pixel defining layer ISL may be disposed between the lower electrode LE and the partition wall CPW and block (e.g., prevent or substantially prevent) electrical connection between the lower electrode LE and the partition wall CPW. That is, the pixel defining layer ISL may help to electrically isolate the lower electrode LE and the partition wall CPW.

The partition wall CPW may be disposed on the pixel defining layer ISL. An upper opening OP-U may be defined in the partition wall CPW. The upper opening OP-U may correspond to the light emitting opening OP-E.

The partition wall CPW may include a first conductive layer CDL1 and a second conductive layer CDL2. The first conductive layer CDL1 may be disposed on the pixel defining layer ISL, and the second conductive layer CDL2 may be disposed on the first conductive layer CDL1. The first conductive layer CDL1 may have a first conductivity, and the second conductive layer CDL2 may have a second conductivity lower than the first conductivity. A thickness of the first conductive layer CDL1 may be greater than a thickness of the second conductive layer CDL2. An etching rate of the first conductive layer CDL1 may be greater than an etching rate of the second conductive layer CDL2. That is, the first conductive layer CDL1 may include a material having a higher etching selectivity than that of the second conductive layer CDL2.

The first conductive layer CDL1 and the second conductive layer CDL2 may include a conductive material. The first conductive layer CDL1 and the second conductive layer CDL2 may include a metal material. Further, the second conductive layer CDL2 may include a material having a lower reflectance than that of the first conductive layer CDL1. Accordingly, the display quality of the display panel DP may be improved by reducing a reflectance on an upper surface of the second conductive layer CDL2 forming an upper surface of the partition wall CPW. For example, the first conductive layer CDL1 may contain aluminum (Al), and the second conductive layer CDL2 may contain titanium (Ti). However, the materials of the first and second conductive layers CDL1 and CDL2 are not limited thereto, and any suitable material may be utilized.

The partition wall CPW may receive the second driving voltage ELVSS (see, e.g., FIG. 4). Accordingly, the second driving voltage ELVSS may be provided to the upper electrode UE in contact with the partition wall CPW.

In FIG. 6, the partition wall CPW has a tapered shape as an example (i.e., an angle θ formed between a lower surface of the partition wall CPW and a side surface of the partition wall CPW may be less than 90 degrees), However the present disclosure is not limited thereto. For example, the partition wall CPW may have a reverse tapered shape. In this case, an angle θ formed between a lower surface of the partition wall CPW and a side surface of the partition wall CPW may exceed 90 degrees.

In a plan view, the upper opening OP-U defined in the second conductive layer CDL2 may overlap the upper opening OP-U defined in the first conductive layer CDL1, and an area of the upper opening OP-U defined in the second conductive layer CDL2 may be smaller than an area of the upper opening OP-U defined in the first conductive layer CDL1.

In a cross sectional view, the upper opening OP-U may include a first area OP-U1 defined by an inner surface of the first conductive layer CDL1 and a second area OP-U2 defined by an inner surface of the second conductive layer CDL2. In a cross sectional view (as shown in FIG. 6), a width and area of the first area OP-U1 may be greater than a width and area of the second area OP-U2. In a cross sectional view, the inner surface of the second conductive layer CDL2 defining the second area OP-U2 may be closer to the center of the lower electrode LE than the inner surface of the first conductive layer CDL1 defining the first area OP-U1. A portion of the second conductive layer CDL2 of the partition wall CPW closer to the center of the lower electrode LE than the inner surface of the first conductive layer CDL1 defining the first area OP-U1 may be defined as a tip portion.

In a plan view, an area of the upper opening OP-U defined in the first conductive layer CDL1 may be greater than an area of the light emitting opening OP-E defined in the pixel defining layer ISL, and the first conductive layer CDL1 may expose a portion of an upper surface of the pixel defining layer ISL by the upper opening OP-U.

The light emitting pattern EP may be disposed on the lower electrode LE. The light emitting pattern EP may include a light emitting layer including a light emitting material.

The light emitting pattern EP may further include a hole injection layer (HIL) and a hole transport layer (HTL) arranged between the lower electrode LE and the light emitting layer and may further include an electron transport layer (ETL) and an electron injection layer (EIL) arranged on the light emitting layer.

The light emitting pattern EP may be patterned by the tip portion defined in the partition wall CPW. The light emitting pattern EP may be disposed inside the lower opening OP-L, the light emitting opening OP-E, and the upper opening OP-U. The light emitting pattern EP may cover a portion of the upper surface of the pixel defining layer ISL exposed from the upper opening OP-U.

According to the present disclosure, the light emitting pattern EP may be patterned and deposited in units of pixels by virtue of the tip portion defined in the partition wall CPW. That is, the light emitting pattern EP may be commonly formed (e.g., concurrently formed) using an open mask but may be easily divided in units of pixels by the partition wall CPW.

When the light emitting pattern EP is patterned using a separate mask (for example, a fine metal mask (FMM)), a support spacer protruding from the partition wall to support the separate mask may be provided. Further, because the separate mask is spaced apart from the base surface, on which the patterning is performed, by a height of the partition wall and the spacer, improvement in a resolution may be limited. Further, as the mask is in contact with the spacer, after the patterning process for the light emitting pattern EP, foreign substances may remain on the spacer, and a damaged spacer may be provided due to stamping of the mask. Accordingly, a defective display panel may be formed.

In the present disclosure, because the light emitting pattern EP is patterned without a separate mask in contact with an internal configuration of the display panel DP, a defect rate is reduced, and thus the display panel DP having improved reliability may be provided. In particular, in manufacturing a large-area display panel DP, the display panel DP may be provided in which process cost may be reduced as production of a large-area mask is omitted, and reliability may be improved as the large-area display panel DP is not affected by defects occurring in the large-area mask.

FIG. 6 exemplarily illustrates a state in which the light emitting pattern EP is not in contact with the inner surface of the first conductive layer CDL1 defining the upper opening OP-U; however, the present disclosure is not limited thereto. For example, the light emitting pattern EP may be in contact with the inner surface of the first conductive layer CDL1 defining the upper opening OP-U.

The upper electrode UE may be disposed on the light emitting pattern EP. The upper electrode UE may be patterned by virtue of the tip portion defined in the partition wall CPW. The upper electrode UE may be in contact with the inner surface of the first conductive layer CDL1 defining the first area OP-U1 of the upper opening OP-U. Therefore, the upper electrode UE may be electrically connected to the partition wall CPW and receive a bias voltage through the partition wall CPW.

According to the present disclosure, as the upper electrode UE is not provided in the form of a common layer overlapping the entire light emitting pattern EP, a leakage current may not occur along the common layer (or any such leakage current may be significantly reduced). Further, as the upper electrode UE is electrically connected to the partition wall CPW having a relatively large thickness, driving resistance is reduced (e.g., the electrical resistance to the driving signal is reduced), and thus the light emitting element ED having an increased light emitting efficiency and having an increased lifetime may be provided.

A capping pattern CP may be disposed on the upper electrode UE inside the upper opening OP-U. The capping pattern CP may be patterned by the tip portion defined in the partition wall CPW. According to some embodiments of the present disclosure, the capping pattern CP may be omitted.

FIG. 6 exemplarily illustrates a state in which the capping pattern CP is not in contact with the inner surface of the first conductive layer CDL1 defining the upper opening OP-U; however, the present disclosure is not limited thereto. For example, the capping pattern CP may be formed to be in contact with the inner surface of the first conductive layer CDL1 defining the upper opening OP-U.

The dummy pattern DMP may be disposed on the partition wall CPW. The dummy pattern DMP may entirely cover the upper surface of the partition wall CPW. The dummy pattern DMP may cover at least a portion of the inner surface of the second conductive layer CDL2 defining the upper opening OP-U. In some examples, a portion of the dummy pattern DMP may overlap the inner surface of the second conductive layer CDL2 defining the second area OP-U2.

The dummy pattern DMP may include an organic layer L1, a conductive layer L2, and a capping layer L3.

The organic layer L1 may be formed by the same process, have the same or substantially the same structure, and include the same or substantially the same material as the light emitting pattern EP. The organic layer L1 may be spaced apart from the light emitting pattern EP. The organic layer L1 may correspond to a residue separated from the light emitting pattern EP by the partition wall CPW when the light emitting pattern EP is commonly formed (e.g., is concurrently formed).

The conductive layer L2 may be disposed on the organic layer L1. The conductive layer L2 may be formed by the same process, have the same or substantially the same structure, and include the same or substantially the same material as the upper electrode UE. The conductive layer L2 may be spaced apart from the upper electrode UE. The conductive layer L2 may correspond to a residue separated from the upper electrode UE by the partition wall CPW when the upper electrode UE is commonly formed (e.g., is concurrently formed).

The capping layer L3 may be disposed on the conductive layer L2. The capping layer L3 may be formed by the same process, have the same or substantially the same structure, and include the same or substantially the same material as the capping pattern CP. The capping layer L3 may be spaced apart from the capping pattern CP. The capping layer L3 may correspond to a residue separated from the capping pattern CP by the partition wall CPW when the capping pattern CP is commonly formed (e.g., concurrently formed).

The thin film encapsulation layer TFE may be disposed on the display element layer DP-OLED. The thin film encapsulation layer TFE may include a lower encapsulation inorganic layer LIL, an encapsulation organic layer OL, and an upper encapsulation inorganic layer UIL.

The lower encapsulation inorganic layer LIL may be formed on the partition wall CPW and the upper electrode UE and may be formed inside the upper opening OP-U. In some examples, the lower encapsulation inorganic layer LIL may cover the dummy pattern DMP and the upper electrode UE (or the capping pattern CP). Further, the lower encapsulation inorganic layer LIL may be in contact with the inner surface of the first conductive layer CDL1 defining the upper opening OP-U. The lower encapsulation inorganic layer LIL may be in contact with a lower surface of the second conductive layer CDL2 exposed from the first conductive layer CDL1. The lower encapsulation inorganic layer LIL may cover the entire upper surface of the dummy pattern DMP. The lower encapsulation inorganic layer LIL may have an integral shape.

The lower encapsulation inorganic layer LIL and the upper encapsulation inorganic layer UIL may protect the display element layer DP-OLED from moisture/oxygen, and the encapsulation organic layer OL may protect the display element layer DP-OLED from foreign substances such as dust particles.

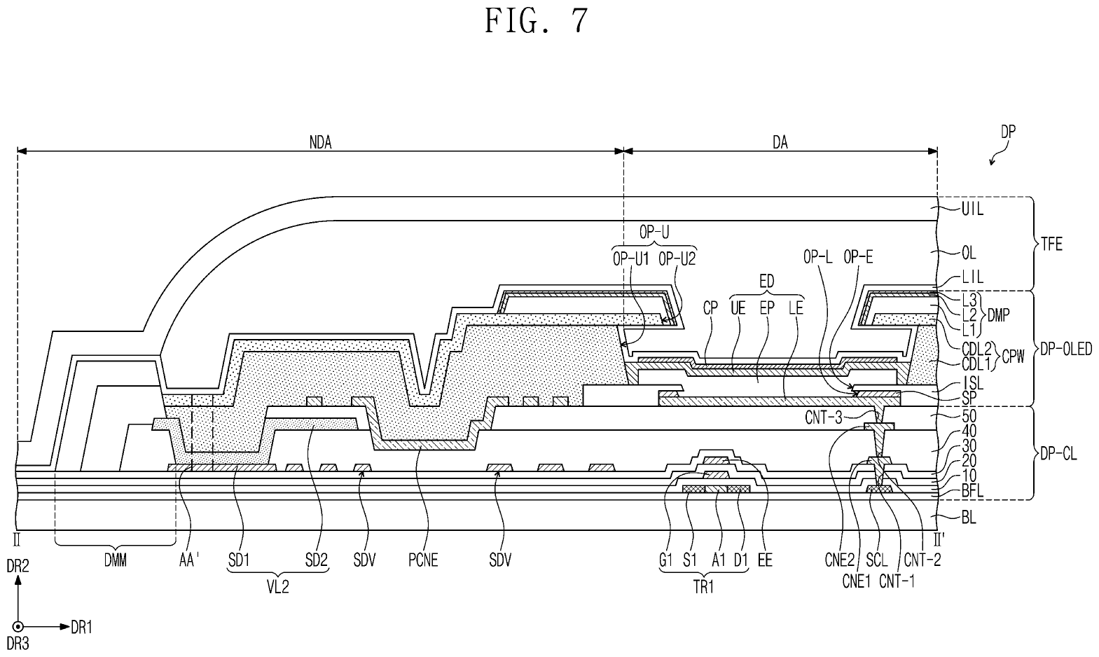

FIG. 7 is a cross-sectional view of the display panel DP along the line II-11′ of FIG. 3. The description of FIG. 7 will be made with reference to FIG. 6, and a description for the same reference numerals may not be repeated. FIG. 7 illustrates the display panel DP including the display area DA and the non-display area NDA.

Referring to FIGS. 6 and 7, the second driving voltage line VL2 may be disposed on the third insulating layer 30 overlapping the non-display area NDA. The second driving voltage line VL2 may include a plurality of layers. For example, the second driving voltage line VL2 may include a first electrode layer SD1 and a second electrode layer SD2. The first electrode layer SD1 may be disposed on the third insulating layer 30, and the second electrode layer SD2 may be disposed on the first electrode layer SD1 and the fourth insulating layer 40. The second electrode layer SD2 may be connected to the first electrode layer SD1. As the second electrode layer SD2 extends to overlap the scan driving unit SDV, a narrow bezel may be implemented (e.g., formed). Thus, even when the width of the first electrode layer SD1 (as, e.g., defined along the first direction) is reduced, the second electrode layer SD2 is provided by extending toward the scan driving unit SDV (e.g., in the first direction), and thus a total resistance of the second driving voltage line VL2 may be reduced. However, this is illustrative, and the second driving voltage line VL2 may include only one of the first electrode layer SD1 and the second electrode layer SD2.

The partition wall CPW may extend from a boundary between the display area DA and the non-display area NDA in a direction away from the display area DA. That is, the partition wall CPW may extend from the boundary between the display area DA and the non-display area NDA in a direction opposite to the first direction DR1. The partition wall CPW extending to the non-display area NDA may be disposed on the pixel defining layer ISL, the fifth insulating layer 50, and the second driving voltage line VL2. The partition wall CPW may be in contact with the second driving voltage line VL2. For example, the partition wall CPW may be in contact with the second electrode layer SD2 of the second driving voltage line VL2. Thus, the upper electrode UE in contact with the partition wall CPW may be electrically connected to the second driving voltage line VL2 in contact with the partition wall CPW. Thus, as the driving voltage is transmitted to the upper electrode UE through the partition wall CPW having a relatively large thickness, a voltage drop of the driving voltage may be reduced.

A portion of the second driving voltage line VL2 may be exposed without being covered by the fifth insulating layer 50 and the pixel defining layer ISL. For example, the portion of the second driving voltage line VL2 may not be overlapped by the fifth insulating layer 50 and the pixel defining layer ISL in a plan view. Thus, the exposed portion of the second driving voltage line VL2 may be in contact with the partition wall CPW. For example, a portion of the second driving voltage line VL2 may be exposed by an additional patterning process after the fifth insulating layer 50 and the pixel defining layer ISL are formed. In some examples, when the fifth insulating layer 50 is patterned, for example, when the connection contact hole CNT-3 is formed, an opening through which a portion of the second driving voltage line VL2 is exposed may be formed together (e.g., concurrently formed), and when the light emitting opening OP-E is formed in the pixel defining layer ISL, the opening through which a portion of the second driving voltage line VL2 is exposed may be formed together (e.g., concurrently formed).

The scan driving unit SDV may include a plurality of thin film transistors formed through the same process as the pixel circuit PDC (see, e.g., FIG. 3) of the pixel PX (see, e.g., FIG. 3).

A dam DMM may be disposed in the non-display area NDA. The dam DMM may include a plurality of insulating layers. For example, the dam DMM may include a first layer formed in the same process as the fourth insulating layer 40, a second layer formed in the same process as the fifth insulating layer 50, and a third layer formed in the same process as the pixel defining layer ISL. However, the present disclosure is not limited thereto, and unlike the illustration of FIG. 7, the dam DMM may include four or more layers. The encapsulation organic layer OL may extend to an area in which the dam DMM is formed. That is, the dam DMM may serve to control flow of a monomer when the encapsulation organic layer OL is formed.

The display panel DP may include an auxiliary connection electrode PCNE. The auxiliary connection electrode PCNE may be formed in the same process as the lower electrode LE. In some embodiments, the auxiliary connection electrode PCNE may be omitted.

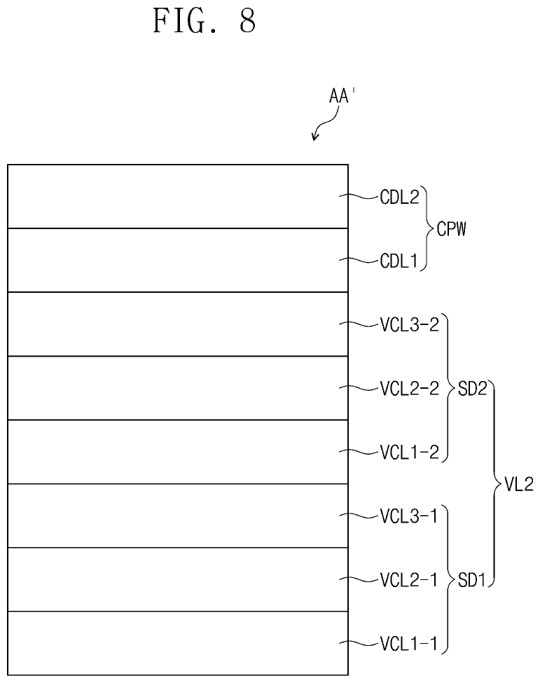

FIG. 8 is an enlarged schematic view of an area corresponding to the area AA′ of FIG. 7. FIG. 8 is a view illustrating the partition wall CPW and the second driving voltage line VL2.

Referring to FIG. 8, the first electrode layer SD1 and the second electrode layer SD2 of the second driving voltage line VL2 may include first voltage conductive layers VCL1-1 and VCL1-2; second voltage conductive layers VCL2-1 and VCL2-2 arranged on the first voltage conductive layers VCL1-1 and VCL1-2, respectively; and third voltage conductive layers VCL3-1 and VCL3-2 arranged on the second voltage conductive layers VCL2-1 and VCL2-2, respectively. That is, the first electrode layer SD1 may include the (1-1)^{th} voltage conductive layer VCL1-1, the (2-1)^{th} voltage conductive layer VCL2-1, and the (3-1)^{th} voltage conductive layer VCL3-1, and the second electrode layer SD2 may include the (1-2)^{th} voltage conductive layer VCL1-2, the (2-2)^{th} voltage conductive layer VCL2-2, and the (3-2)^{th} voltage conductive layer VCL3-2.

A thickness of the second voltage conductive layers VCL2-1 and VCL2-2 may be greater than those of the first voltage conductive layers VCL1-1 and VCL1-2, and those of the third voltage conductive layers VCL3-1 and VCL3-2. The first voltage conductive layers VCL1-1 and VCL1-2 and the third voltage conductive layers VCL3-1 and VCL3-2 may include a first material, and the second voltage conductive layers VCL2-1 and VCL2-2 may include a second material different from the first material. Conductivity of the first material may be lower than that of the second material. The first conductive layer CDL1 and the second voltage conductive layers VCL2-1 and VCL2-2 may include the same or substantially the same material; and the second conductive layer CDL2, the first voltage conductive layers VCL1-1 and VCL1-2, and the third voltage conductive layers VCL3-1 and VCL3-2 may include the same or substantially the same material. For example, the first conductive layer CDL1 and the second voltage conductive layers VCL2-1 and VCL2-2 may contain aluminum (Al), and the second conductive layer CDL2, the first voltage conductive layers VCL1-1 and VCL1-2, and the third voltage conductive layers VCL3-1 and VCL3-2 may contain titanium (Ti). However, the materials of the first and second conductive layers CDL1 and CDL2 and the first to third voltage conductive layers VCL1-1, VCL1-2, VCL2-1, VCL2-2, VCL3-1, and VCL3-2 are not limited to the above, and may be suitably modified.

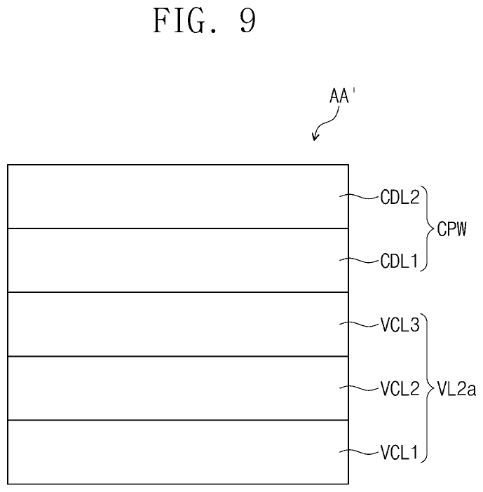

FIG. 9 is an enlarged schematic view of an area corresponding to the area AA′ of FIG. 7. FIG. 9 is a view illustrating the partition wall CPW and the second driving voltage line VL2.

Referring to FIG. 9, the second driving voltage line VL2 may include one of the first electrode layer SD1 (see, e.g., FIG. 7) and the second electrode layer SD2 (see, e.g., FIG. 7). The second driving voltage line VL2 may include a first voltage conductive layer VCL1, a second voltage conductive layer VCL2 disposed on the first voltage conductive layer VCL1, and a third voltage conductive layer VCL3 disposed on the second voltage conductive layer VCL2.

A thickness of the second voltage conductive layer VCL2 may be greater than those of the first voltage conductive layer VCL1 and the third voltage conductive layer VCL3. The first voltage conductive layer VCL1 and the third voltage conductive layer VCL3 may include a first material, and the second voltage conductive layer VCL2 may include a second material different from the first material. Conductivity of the first material may be lower than that of the second material. The first conductive layer CDL1 and the second voltage conductive layer VCL2 may include the same or substantially the same material, and the second conductive layer CDL2, the first voltage conductive layer VCL1, and the third voltage conductive layer VCL3 may include the same or substantially the same material. For example, the first conductive layer CDL1 and the second voltage conductive layer VCL2 may contain aluminum (Al); and the second conductive layer CDL2, the first voltage conductive layer VCL1, and the third voltage conductive layer VCL3 may contain titanium (Ti). However, the materials of the first and second conductive layers CDL1 and CDL2 and the first to third voltage conductive layers VCL1, VCL2, and VCL3 are not limited to the above, and may be suitably modified.

Referring to FIGS. 7 to 9, the second driving voltage line VL2 or VL2a may include the first to third voltage conductive layers VCL1-1, VCL1-2, VCL2-1, VCL2-2, VCL3-1, and VCL3-2 or VCL1, VCL2, and VCL3; and the partition wall CPW may include the first and second conductive layers CDL1 and CDL2. The third voltage conductive layer VCL3-2 or VCL3 of the second driving voltage line VL2 or VL2a may be in contact with the second conductive layer CDL2 of the partition wall CPW, and adhesion reliability may be improved (e.g., increased) by the above material properties.

According to the above description, an upper electrode and a driving voltage line are electrically connected by a partition wall. Thus, as the driving voltage is transmitted to the upper electrode through the partition wall having a relatively large thickness, a voltage drop of the driving voltage may be reduced.

Further, a conductive layer of the driving voltage line and a conductive layer of the partition wall may include different materials and may be in contact with each other. For example, because the conductive layer of the driving voltage line containing titanium and the conductive layer of the partition wall containing aluminum are in contact with each other, adhesion reliability may be improved (e.g., increased) due to material characteristics.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Although the description has been made above with reference to some embodiments of the present disclosure, it may be understood that those skilled in the art or those having ordinary knowledge in the art may variously modify and make changes, in a suitable manner, to the embodiments of the present disclosure without departing from the spirit and technical scope of the present disclosure, as defined by the appended claims, and equivalents thereof. Accordingly, the technical scope of the present disclosure is not limited to the detailed description of the specification, but should instead be defined by the appended claims.

What is claimed is:

1. A display panel comprising:
a base layer comprising a display area and a non-display area adjacent to the display area;
a lower electrode on the base layer and overlapping the display area;
a driving voltage line on the base layer and overlapping the non-display area;
a pixel defining layer on the base layer, covering a portion of the lower electrode, and defining a light emitting opening;
a light emitting pattern within the light emitting opening and on the lower electrode;
a partition wall on the pixel defining layer and the driving voltage line and defining an upper opening corresponding to the light emitting opening; and
an upper electrode on the light emitting pattern and in contact with an inner surface of the partition wall defining the upper opening,
wherein the driving voltage line is in contact with the partition wall.

2. The display panel of claim 1, wherein the partition wall extends from a boundary between the display area and the non-display area in a direction away from the display area.

3. The display panel of claim 1, wherein the upper electrode and the driving voltage line are electrically connected.

4. The display panel of claim 1, wherein the partition wall comprises:
a first conductive layer having a first conductivity; and
a second conductive layer having a second conductivity lower than the first conductivity, and on the first conductive layer.

5. The display panel of claim 4, wherein a thickness of the first conductive layer is greater than a thickness of the second conductive layer.

6. The display panel of claim 4, wherein an inner surface of the first conductive layer defines a first area of the upper opening, and an inner surface of the second conductive layer defines a second area of the upper opening, and
wherein the inner surface of the second conductive layer defining the second area is closer to a center of the lower electrode than the inner surface of the first conductive layer defining the first area in a cross sectional view.

7. The display panel of claim 4, further comprising:
a lower encapsulation inorganic layer on the upper electrode and the partition wall;
an encapsulation organic layer on the lower encapsulation inorganic layer; and
an upper encapsulation inorganic layer on the encapsulation organic layer,
wherein the lower encapsulation inorganic layer is in contact with a side surface of the first conductive layer and a lower surface of the second conductive layer.

8. The display panel of claim 7, further comprising:
a capping pattern between the upper electrode and the lower encapsulation inorganic layer.

9. The display panel of claim 4, wherein the driving voltage line comprises:
a first voltage conductive layer comprising a first material;
a second voltage conductive layer on the first voltage conductive layer and comprising a second material different from the first material; and
a third voltage conductive layer on the second voltage conductive layer and comprising the first material.

10. The display panel of claim 9, wherein a conductivity of the first material is lower than that of the second material.

11. The display panel of claim 9, wherein a thickness of the second voltage conductive layer is greater than thicknesses of the first voltage conductive layer and the third voltage conductive layer.

12. The display panel of claim 9, wherein the first conductive layer and the second voltage conductive layer comprise the same material, and
wherein the second conductive layer, the first voltage conductive layer, and the third voltage conductive layer comprise the same material.

13. The display panel of claim 9, wherein the driving voltage line comprises a first electrode layer and a second electrode layer on the first electrode layer, the second electrode layer being in contact with the partition wall.

14. A display panel comprising:
a base layer comprising a display area and a non-display area adjacent to the display area;
a lower electrode on the base layer overlapping the display area;
a driving voltage line on the base layer overlapping the non-display area;
a pixel defining layer on the base layer, covering a portion of the lower electrode, and defining a light emitting opening;
a light emitting pattern within the light emitting opening and on the lower electrode;
a partition wall defining an upper opening corresponding to the light emitting opening; and
an upper electrode on the light emitting pattern and in contact with an inner surface of the partition wall defining the upper opening,
wherein the partition wall extends from a boundary between the display area and the non-display area in a direction away from the display area and electrically connects the upper electrode and the driving voltage line.

15. The display panel of claim 14, wherein the driving voltage line is in contact with the partition wall.

16. The display panel of claim 14, wherein the partition wall comprises:
a first conductive layer having a first conductivity; and
a second conductive layer having a second conductivity lower than the first conductivity, and on the first conductive layer.

17. The display panel of claim 16, wherein an inner surface of the first conductive layer defines a first area of the upper opening, and an inner surface of the second conductive layer defines a second area of the upper opening, and
wherein the inner surface of the second conductive layer defining the second area is closer to a center of the lower electrode than the inner surface of the first conductive layer defining the first area in a cross section.

18. The display panel of claim 16, wherein the driving voltage line comprises:
a first voltage conductive layer comprising a first material;
a second voltage conductive layer on the first voltage conductive layer and comprising a second material different from the first material; and
a third voltage conductive layer on the second voltage conductive layer and comprising the first material, and
wherein a conductivity of the first material is lower than a conductivity of the second material.

19. The display panel of claim 18, wherein the first conductive layer and the second voltage conductive layer comprise the same material, and
wherein the second conductive layer, the first voltage conductive layer, and the third voltage conductive layer comprise the same material.

20. The display panel of claim 18, wherein the driving voltage line comprises a first electrode layer and a second electrode layer on the first electrode layer, the second electrode layer being in contact with the partition wall.
